(19) United States
(12) Patent Application Publication
(10) Pub. No.: US 2004/0075119 A1
(43) Pub. Date: Apr. 22, 2004

(54) Forming polysilicon structures

(76) Inventors: Sanjay Natarajan, Portland, OR (US); Ibrahim Ban, Beaverton, OR (US); Kevin Heidrich, Beaverton, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/266,427

(22) Filed: Oct. 8, 2002

(51) Int. Cl. H01L 29/76; H01L 29/94

(52) U.S. Cl. 257/288

(57) ABSTRACT

A doped polysilicon structure may be formed without the need to etch doped polysilicon. The patterned polysilicon may be covered, an opening may be formed in the polysilicon covering, and then the polysilicon may be doped through the opening. As a result, awkward etching of doped polysilicon may be avoided in some cases.

### BACKGROUND

This invention relates generally to the formation of polysilicon structures including the formation of polysilicon gate electrodes.

Conventionally, polysilicon gate electrodes are formed by depositing polysilicon over a substrate that may be covered with a suitable gate dielectric. The polysilicon material is then doped, for example, using an ion implantation process.

It is then necessary to define the polysilicon electrodes from the doped polysilicon layer using etching techniques. However, etching doped polysilicon presents significant challenges. These challenges include known profile and differential etch bias issues.

Thus, there is a need to find a way to form polysilicon structures, such as gate electrodes, without necessitating the etching of heavily doped polysilicon material.

### BRIEF DESCRIPTION OF THE DRAWINGS

FIG. 1 is an enlarged cross-sectional view of an embodiment of the present invention at an early stage of manufacture;

FIG. 2 is an enlarged cross-sectional view corresponding to FIG. 1 at a subsequent stage in accordance with one embodiment of the present invention;

FIG. 3 is an enlarged cross-sectional view corresponding to FIG. 2 at a subsequent stage in accordance with one embodiment of the present invention;

FIG. 4 is an enlarged cross-sectional view at a subsequent stage in accordance with one embodiment of the present invention; and

FIG. 5 is an enlarged cross-sectional view at a subsequent stage in accordance with one embodiment of the present invention.

### DETAILED DESCRIPTION

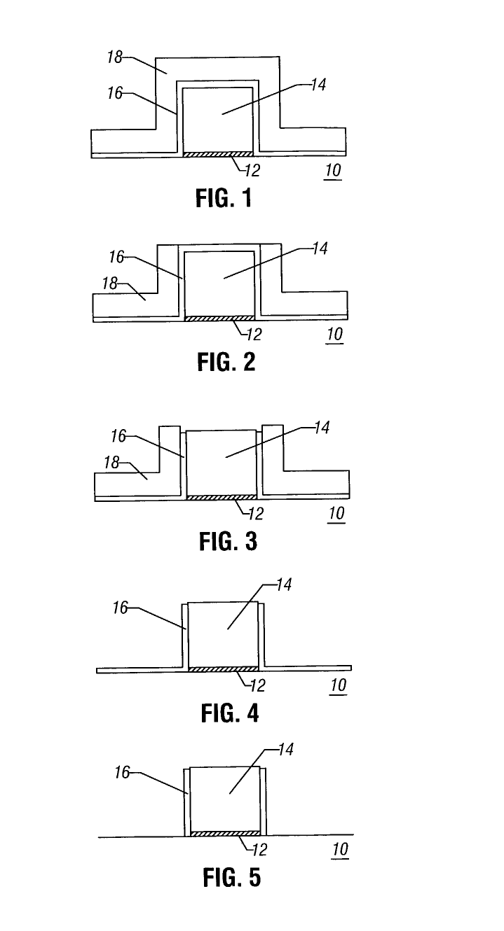

Referring to FIG. 1, a semiconductor substrate may have a polysilicon material formed over a suitable gate dielectric. The substrate may, for example, be a silicon substrate and the gate dielectric may be an oxide, for example. The polysilicon material may then be patterned to form the polysilicon gate material 14 over a gate dielectric 12, all positioned over a substrate 10, as shown in FIG. 1. Because the polysilicon material is undoped or substantially undoped when etched, it may be more easily etched and patterned to define the shape shown in FIG. 1.

By “substantially undoped,” it is intended to refer to a polysilicon material that either has no doping or doping at levels substantially lower than the doping levels utilized to form doped polysilicon gate electrodes that are either n-type or p-type. Generally, these gate electrodes are considered heavily doped and have doping concentrations of greater than 1E18 atoms per cm³.

The gate material 14 may be covered by a relatively thinner layer 16 and a relatively thicker layer 18. In one embodiment the layer 16 may be an insulator such as silicon dioxide. The layer 18 may, for example, be an insulator such as silicon nitride or a combination of layers of silicon nitride and silicon dioxide, as two examples.

The structure shown in FIG. 2 may be subjected to a conventional planarization step such as a chemical mechanical planarization (CMP) operation. The planarization may utilize the thinner layer 16 as a planarization stop in one embodiment. Thus, as shown in FIG. 2, the upper portion of the thicker layer 18 may be removed down to the height of the uppermost portion of the thinner layer 16.

The exposed portion of the thinner layer 16 may then be removed using any suitable technique. One suitable technique is a wet etch using hydrofluoric or H₃PO₄ etchant, for example. The resulting structure, shown in FIG. 3, has the upper portion of the thinner layer 16 removed and possibly a little bit of the gate material 14. In case some of the gate material 14 is removed, the initial structure of the gate electrode 14 may be slightly higher than is needed to account for the ensuing loss of material.

In an embodiment in which polysilicon gate electrodes for complementary metal oxide semiconductor (CMOS) technologies are involved, a photodefinition process may be used to define n-type and p-type areas. The n-type areas may include n-type doped polysilicon gate electrodes and the p-type areas may include p-type doped polysilicon gate electrodes.

An ion implantation or other doping process may be utilized to appropriately dope the polysilicon material 14. For example, when the n-type areas are doped, a suitable dopant may be utilized to dope the gate material 14 in the p-type doped areas with the n-type areas covered and with the p-type areas covered, a suitable dopant may be utilized to dope the n-type areas. It may be appreciated that since the doping is done after the definition of the gate material 14, the need to etch heavily doped polysilicon may be largely, if not completely, avoided.

Referring to FIG. 4, a suitable etching process may be utilized to remove the thicker layer 18. For example, a wet etch may be utilized in one embodiment.

Referring to FIG. 5, the horizontal portion of the thinner insulator 16 may then be removed using an anisotropic etch process, such as a dry etch in one embodiment. As a result, a portion of the thinner layer 16 may remain and this may function as a sidewall spacer in some embodiments.

Alternatively, the thinner layer 16 may be completely removed, for example, using an isotropic etch such as an isotropic wet etch.

In some embodiments, polysilicon material may be defined and patterned without the need to etch heavily doped polysilicon. As a result, the quality and feasibility of the etching process may be improved in some situations.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
patterning a substantially undoped polysilicon material; and
doping the patterned polysilicon material.

2. The method of claim 1 including forming a polysilicon gate electrode from said polysilicon material.

3. The method of claim 2 including forming n-type and p-type polysilicon gate electrodes from said polysilicon material.

4. The method of claim 1 including covering the patterned polysilicon with a first material.

5. The method of claim 4 including planarizing the covered polysilicon material.

6. The method of claim 5 including doping the polysilicon material after planarizing the covered polysilicon material.

7. The method of claim 6 including removing said first material after doping said polysilicon material.

8. The method of claim 4 wherein covering said polysilicon material includes providing a covering including a first thinner layer and a second thicker layer.

9. The method of claim 8 including covering said polysilicon material with a first thinner layer formed of silicon dioxide.

10. The method of claim 9 including covering said first thinner layer with a second thicker layer including silicon nitride.

11. The method of claim 8 including removing said thicker layer and leaving at least a portion of said thinner layer.

12. The method of claim 4 including exposing said polysilicon material using planarization.

13. The method of claim 12 including planarizing said covered polysilicon material down to a planarization stop layer in said covering.

14. The method of claim 13 including removing said planarization stop layer to expose said polysilicon material and then implanting said polysilicon material.

15. A semiconductor structure comprising:
a substrate; and
a patterned polysilicon material on said substrate, said patterned polysilicon material being substantially undoped.

16. The structure of claim 15 wherein said polysilicon material is covered by a cover material.

17. The structure of claim 16 wherein said cover material includes an insulator.

18. The structure of claim 16 wherein said cover material includes two distinct layers.

19. The structure of claim 18 wherein one of said layers is thicker than the other of said layers.

20. The structure of claim 18 wherein said cover material includes a first layer of silicon dioxide and a second layer of a different insulative material.

21. The structure of claim 20 wherein said polysilicon material is exposed through said cover material.

22. A method comprising:
patterning a substantially undoped polysilicon material;
covering the substantially undoped polysilicon material;
forming an opening through said covering; and
doping the patterned polysilicon material through said opening.

23. The method of claim 22 including planarizing said covering to form said opening.

24. The method of claim 23 wherein covering said polysilicon material includes providing a covering including a first thinner layer and a second thicker layer.

25. The method of claim 24 including covering said polysilicon material with a first thinner layer formed of silicon dioxide.

26. The method of claim 25 including covering said first thinner layer with a second thicker layer including silicon nitride.

27. The method of claim 24 including removing said second thicker layer and leaving at least a portion of said first thinner layer.

28. The method of claim 27 including planarizing said covering through said second thicker layer down to the first thinner layer.

29. The method of claim 28 including forming said opening by etching through said first thinner layer to expose said polysilicon material.

30. The method of claim 29 including implanting said polysilicon material through said opening.
